(19) United States
(12) Patent Application Publication
(10) Pub. No.: US 2005/0048291 A1
(43) Pub. Date: Mar. 3, 2005

(54) Nano-filled composite materials with exceptionally high glass transition temperature

(75) Inventors: Wing Keung Woo, Clifton Park, NY (US); Slawomir Rubinsztajn, Niskayuna, NY (US); John Robert Campbell, Clifton Park, NY (US); Florian Johannes Schattenmann, Ballston Lake, NY (US); Sandeep Shrikant Tonapi, Niskayuna, NY (US); Ananth Prabhakumar, Schenectady, NY (US)

Correspondence Address: General Electric Company;CRD Patent Docket Rm 4A59, Bldg. K-1, P.O. Box 8, Schenectady, NY, 12301, US

(73) Assignee: General Electric Company

(21) Appl. No.: 10/641,425

(22) Filed: Aug. 14, 2003

(51) Int. Cl. B32B 27/38; H01L 21/56; C08L 63/00

(52) U.S. Cl. 428/413; 438/127; 523/440

(57) ABSTRACT

A curable epoxy formulation is provided in the present invention. The formulation comprises an epoxy monomer, an organofunctionalized colloidal silica having a particle size in a range between about 2 nanometers and about 20 nanometers, and optional reagents wherein the organofunctionalized colloidal silica substantially increases the glass transition temperature of the epoxy formulation. Further embodiments of the present invention include a semiconductor package comprising the aforementioned curable epoxy formulation.

### BACKGROUND OF THE INVENTION

The present invention is related to epoxy compositions. More particularly, the present invention is related to high glass transition temperature curable epoxy compositions.

Demand for smaller and more sophisticated electronic devices continues to drive the electronic industry towards improved integrated circuits packages that are capable of supporting higher input/output (I/O) density as well as have enhanced performance at smaller die areas. Flip chip technology fulfills these demanding requirements. A weak point of the flip chip construction is the significant mechanic stress experienced by solder bumps during thermal cycling due to the coefficient of thermal expansion (CTE) mismatch between silicon die and substrate that, in turn, causes mechanical and electrical failures of the electronic devices. Currently, capillary underfill is used to fill gaps between silicon chip and substrate and improves the fatigue life of solder bumps. Unfortunately, many encapsulant compounds suffer from the inability to fill small gaps (50-100 um) between the chip and substrate due to high filler content and high viscosity of the encapsulant.

In some applications improved transparency is needed to enable efficient dicing of a wafer to which underfill materials have been applied. In no-flow underfill applications, it is also desirable to avoid entrapment of filler particles during solder joint formation. Thus, there remains a need to find an encapsulant material that has a sufficiently low viscosity and low coefficient of thermal expansion such that it can fill small gaps between chips and substrates. Additionally, the encapsulant material should have a sufficient glass transition temperature to allow the solder joints to melt and form electrical connections.

The present invention provides a curable epoxy formulation comprising at least one epoxy monomer, at least one organofunctionalized colloidal silica having a particle size in a range between about 2 nanometers and about 20 nanometers, and optional reagents wherein the organofunctionalized colloidal silica substantially increases the glass transition temperature of the epoxy formulation.

In another embodiment, the present invention further provides a semiconductor package comprising at least one chip, at least one substrate, and an encapsulant, wherein the encapsulant encapsulates at least a portion of the chip on the substrate and wherein the encapsulant comprises at least one epoxy monomer, at least one organofunctionalized colloidal silica having a particle size in a range between about 2 nanometers and about 20 nanometers, and optional reagents wherein the organofunctionalized colloidal silica substantially increases the glass transition temperature of the epoxy formulation.

### DETAILED DESCRIPTION OF THE INVENTION

It has been found that the use of at least one epoxy resin, at least one functionalized colloidal silica having a particle size in a range between about 2 nanometers and about 20 nanometers, and optional reagents provides a curable epoxy formulation with a substantially increased glass transition temperature. “Substantially increased glass transition temperature” as used herein refers to an increase in glass transition temperature of greater than about 20° C. compared to a formulation without functionalized colloidal silica. Typically, the cured composition of the present invention has a glass transition temperature (Tg) of at least about 200° C. and preferably, at least about 220° C. The curable epoxy formulation of the present invention also has a low viscosity of the total curable epoxy formulation before cure and whose cured parts have a low coefficient of thermal expansion (CTE). “Low coefficient of thermal expansion” as used herein refers to a cured total composition with a coefficient of thermal expansion lower than that of the base resin as measured in parts per million per degree centigrade (ppm/° C.). Typically, the coefficient of thermal expansion of the cured total composition is below about 50 ppm/° C. “Low viscosity of the total composition before cure” typically refers to a viscosity of the epoxy formulation in a range between about 50 centipoise and about 100,000 centipoise and preferably, in a range between about 100 centipoise and about 20,000 centipoise at 25° C. before the composition is cured. In another aspect of the invention, the formulated molding compound used for a transfer molding encapsulation typically has a viscosity in range between about 10 poise and about 5,000 poise and preferably, in range between about 50 poise and about 200 poise at molding temperature. Additionally, the above molding compound typically has a spiral flow in a range between about 15 inches and about 100 inches and preferably, in range between about 25 inches and about 75 inches. “Cured” as used herein refers to a total formulation with reactive groups wherein in a range between about 50% and about 100% of the reactive groups have reacted.

Epoxy resins are curable monomers and oligomers that are blended with the functionalized colloidal silica. Epoxy resins include any organic system or inorganic system with an epoxy functionality. The epoxy resins useful in the present invention include those described in “Chemistry and Technology of the Epoxy Resins,” B. Ellis (Ed.) Chapman Hall 1993, New York and “Epoxy Resins Chemistry and Technology,” C. May and Y. Tanaka, Marcell Dekker 1972, New York. Epoxy resins that can be used for the present invention include those that could be produced by reaction of a hydroxyl, carboxyl or amine containing compound with epichlorohydrin, preferably in the presence of a basic catalyst, such as a metal hydroxide, for example sodium hydroxide. Also included are epoxy resins produced by reaction of a compound containing at least one and preferably two or more carbon-carbon double bonds with a peroxide, such as a peroxyacid.

Preferred epoxy resins for the present invention are cycloaliphatic and aliphatic epoxy resins. Aliphatic epoxy resins include compounds that contain at least one aliphatic group and at least one epoxy group. Examples of aliphatic epoxies include, butadiene dioxide, dimethylpentane dioxide, diglycidyl ether, 1,4-butanedioldiglycidyl ether, diethylene glycol diglycidyl ether, and dipentene dioxide.

Cycloaliphatic epoxy resins are well known to the art and, as described herein, are compounds that contain at least about one cycloaliphatic group and at least one oxirane group. More preferred cycloaliphatic epoxies are compounds that contain about one cycloaliphatic group and at least two oxirane rings per molecule. Specific examples include 3-cyclohexenylmethyl-3-cyclohexenylcarboxylate diepoxide, 2-(3,4-epoxy)cyclohexyl-5,5-spiro-(3,4-epoxy)cyclohexane-m-dioxane, 3,4-epoxycyclohexylalkyl-3,4-epoxycyclohexanecarboxylate, 3,4-epoxy-6-methylcyclohexylmethyl-3,4-epoxy-6-methylcyclohexanecarboxylate, vinyl cyclohexanedioxide, bis(3,4-epoxycyclohexylmethyl)adipate, bis(3,4-epoxy-6-methylcyclohexylmethyl)adipate, exo-exo bis(2,3-epoxycyclopentyl)ether, endo-exo bis(2,3-epoxycyclopentyl)ether, 2,2-bis(4-(2,3-epoxypropoxy)cyclohexyl)propane, 2,6-bis(2,3-epoxypropoxycyclohexyl-p-dioxane), 2,6-bis(2,3-epoxypropoxy)norbornene, the diglycidylether of linoleic acid dimer, limonene dioxide, 2,2-bis(3,4-epoxycyclohexyl)propane, dicyclopentadiene dioxide, 1,2-epoxy-6-(2,3-epoxypropoxy)hexahydro-4,7-methanoindane, p-(2,3-epoxy)cyclopentylphenyl-2,3-epoxypropylether, 1-(2,3-epoxypropoxy)phenyl-5,6-epoxyhexahydro-4,7-methanoindane, o-(2,3-epoxy)cyclopentylphenyl-2,3-epoxypropyl ether), 1,2-bis(5-(1,2-epoxy)-4,7-hexahydromethanoindanoxyl)ethane, cyclopentenylphenyl glycidyl ether, cyclohexanediol diglycidyl ether, and diglycidyl hexahydrophthalate. Typically, the cycloaliphatic epoxy resin is 3-cyclohexenylmethyl-3-cyclohexenylcarboxylate diepoxide.

Aromatic epoxy resins may also be used with the present invention. Examples of epoxy resins useful in the present invention include bisphenol-A epoxy resins, bisphenol-F epoxy resins, phenol novolac epoxy resins, cresol-novolac epoxy resins, biphenol epoxy resins, biphenyl epoxy resins, 4,4′-biphenyl epoxy resins, polyfunctional epoxy resins, divinylbenzene dioxide, and 2-glycidylphenylglycidyl ether. When resins, including aromatic, aliphatic and cycloaliphatic resins are described throughout the specification and claims, either the specifically-named resin or molecules having a moiety of the named resin are envisioned.

Silicone-epoxy resins that may be used with the present invention typically have the formula:
MₐM′_{b}D_{c}D′_{d}TₑT′_{f}Q_{g}

where the subscripts a, b, c, d, e, f and g are zero or a positive integer, subject to the limitation that the sum of the subscripts b, d and f is one or greater; where M has the

| | |
|---|---|
| formula: | R¹₃SiO_{1/2}, |
| M′ has the formula: | (Z)R²₂SiO_{1/2}, |
| D has the formula: | R³₂SiO_{2/2}, |
| D′ has the formula: | (Z)R⁴SiO_{2/2}, |
| T has the formula: | R⁵SiO_{3/2}, |
| T′ has the formula: | (Z)SiO_{3/2}, |
| and Q has the formula: | SiO_{4/2}, |

wherein each R¹, R², R³, R⁴, R⁵ is independently at each occurrence a hydrogen atom, C₁₋₂₂ alkyl, C₁₋₂₂ alkoxy, C₂₋₂₂ alkenyl, C₆₋₁₄ aryl, C₆₋₂₂ alkyl-substituted aryl, or C₆₋₂₂ arylalkyl which groups may be halogenated, for example, fluorinated to contain fluorocarbons such as C₁₋₂₂ fluoroalkyl, or may contain amino groups to form aminoalkyls, for example aminopropyl or aminoethylaminopropyl, or may contain polyether units of the formula (CH₂CHR⁶O)ₖ where R⁶ is CH₃ or H and k is in a range between about 4 and 20; and Z, independently at each occurrence, represents an epoxy group. The term “alkyl” as used in various embodiments of the present invention is intended to designate both normal alkyl, branched alkyl, aralkyl, and cycloalkyl radicals. Normal and branched alkyl radicals are preferably those containing in a range between about 1 and about 12 carbon atoms, and include as illustrative non-limiting examples methyl, ethyl, propyl, isopropyl, butyl, tertiary-butyl, pentyl, neopentyl, and hexyl. Cycloalkyl radicals represented are preferably those containing in a range between about 4 and about 12 ring carbon atoms. Some illustrative non-limiting examples of these cycloalkyl radicals include cyclobutyl, cyclopentyl, cyclohexyl, methylcyclohexyl, and cycloheptyl. Preferred aralkyl radicals are those containing in a range between about 7 and about 14 carbon atoms; these include, but are not limited to, benzyl, phenylbutyl, phenylpropyl, and phenylethyl. Aryl radicals used in the various embodiments of the present invention are preferably those containing in a range between about 6 and about 14 ring carbon atoms. Some illustrative non-limiting examples of these aryl radicals include phenyl, biphenyl, and naphthyl. An illustrative non-limiting example of a suitable halogenated moiety is trifluoropropyl. Combinations of epoxy monomers and oligomers may be used in the present invention.

Colloidal silica is a dispersion of submicron-sized silica (SiO₂) particles in an aqueous or other solvent medium. The colloidal silica contains up to about 95 weight % of silicon dioxide (SiO₂) and typically up to about 80 weight % of silicon dioxide. The particle size of the colloidal silica is typically in a range between about 2 nanometers (nm) and about 20 nm, and more typically in a range between about 2 nm and about 10 nm. The colloidal silica is functionalized with an organoalkoxysilane to form (via infra) an organofunctionalized colloidal silica.

Organoalkoxysilanes used to functionalize the colloidal silica are included within the formula:
(R⁷)ₐSi(OR⁸)₄₋ₐ,
where R⁷ is independently at each occurrence a C₁₋₁₈ monovalent hydrocarbon radical optionally further functionalized with alkyl acrylate, alkyl methacrylate or epoxide groups or C₆₋₁₄ aryl or alkyl radical; R⁸ is independently at each occurrence a C₁₋₁₈ monovalent hydrocarbon radical or a hydrogen radical; and “a” is a whole number equal to 1 to 3 inclusive. Preferably, the organoalkoxysilanes included in the present invention are 2-(3,4-epoxy cyclohexyl)ethyltrimethoxysilane, 3-glycidoxypropyltrimethoxysilane, phenyltrimethoxysilane, and methacryloxypropyltrimethoxysilane. A combination of functionality is possible. Typically, the organoalkoxysilane is present in a range between about 5 weight % and about 60 weight % based on the weight of silicon dioxide contained in the colloidal silica. The resulting organofunctionalized colloidal silica can be treated with an acid or base to neutralize the pH. Optional reagents such as an acid or base as well as other catalysts promoting condensation of silanol and alkoxysilane groups may also be used to aid the functionalization process. Such catalyst include organo-titane and organo-tin compounds such as tetrabutyl titanate, titanium isopropoxybis(acetylacetonate), dibutyltin dilaurate, or combinations thereof.

The functionalization of colloidal silica may be performed by adding the organoalkoxysilane functionalization agent to a commercially available aqueous dispersion of colloidal silica in the weight ratio described above to which an aliphatic alcohol has been added. The resulting composition comprising the functionalized colloidal silica and the organoalkoxysilane functionalization agent in the aliphatic alcohol is defined herein as a pre-dispersion. The aliphatic alcohol may be selected from, but not limited to, isopropanol, t-butanol, 2-butanol, and combinations thereof. The amount of aliphatic alcohol is typically in a range between about 1 fold and about 10 fold of the amount of silicon dioxide present in the aqueous colloidal silica pre-dispersion. In some cases, stabilizers such as 4-hydroxy-2,2,6,6-tetramethylpiperidinyloxy (i.e. 4-hydroxy TEMPO) may be added to this pre-dispersion. In some instances small amounts of acid or base may be added to adjust the pH of the transparent pre-dispersion. “Transparent” as used herein refers to a maximum haze percentage of 15, typically a maximum haze percentage of 10; and most typically a maximum haze percentage of 3. The resulting pre-dispersion is typically heated in a range between about 50° C. and about 100° C. for a period in a range between about 1 hour and about 5 hours.

The cooled transparent organic pre-dispersion is then further treated to form a final dispersion of the functionalized colloidal silica by addition of curable epoxy monomers or oligomers and optionally, more aliphatic solvent which may be selected from, but not limited to, isopropanol, 1-methoxy-2-propanol, 1-methoxy-2-propyl acetate, toluene, and combinations thereof. This final dispersion of the functionalized colloidal silica may be treated with acid or base or with ion exchange resins to remove acidic or basic impurities.

In some instances, the pre-dispersion or the final dispersion of the functionalized colloidal silica may be further functionalized through the optional addition of a capping agent. Low boiling components are at least partially removed and subsequently, an appropriate capping agent that will react with residual hydroxyl functionality of the functionalized colloidal silica is added in an amount in a range between about 0.05 times and about 10 times the amount of silicon dioxide present in the pre-dispersion or final dispersion. Partial removal of low boiling components as used herein refers to removal of at least about 10% of the total amount of low boiling components, and preferably, at least about 50% of the total amount of low boiling components. The dispersion with capping agent is then heated in a range between about 20° C. and about 140° C. for a period of time in a range between about 0.5 hours and about 48 hours. The resultant mixture is then filtered. An effective amount of capping agent caps the functionalized colloidal silica. “Capped functionalized colloidal silica” is defined herein as a functionalized colloidal silica in which at least 10%, preferably at least 20%, more preferably at least 35%, of the free hydroxyl groups present in the corresponding uncapped functionalized colloidal silica have been functionalized by reaction with a capping agent. Capping the functionalized colloidal silica effectively improves the cure of the total curable epoxy formulation by improving room temperature stability of the epoxy formulation. Formulations which include the capped functionalized colloidal silica show much better room temperature stability than analogous formulations in which the colloidal silica has not been capped.

Exemplary capping agents include hydroxyl reactive materials such as silylating agents. Examples of a silylating agent include, but are not limited to hexamethyldisilazane (HMDZ), tetramethyldisilazane, divinyltetrametyldisilazane, diphenyltetramethyldisilazane, N-(trimethylsilyl)diethylamine, 1-(trimethylsilyl)imidazole, trimethylchlorosilane, pentamethylchlorodisiloxane, pentamethyldisiloxane, and combinations thereof If the pre-dispersion is reacted with the capping agent, at least one curable epoxy monomer is added to form the final dispersion.

The final dispersion of the functionalized colloidal silica is concentrated under a vacuum in a range between about 0.5 Torr and about 250 Torr and at a temperature in a range between about 20° C. and about 140° C. to substantially remove any low boiling components such as solvent, residual water, and combinations thereof to give a transparent dispersion of functionalized colloidal silica in a curable epoxy monomer, herein referred to as a “final concentrated dispersion”. Substantial removal of low boiling components is defined herein as removal of at least about 90% of the total amount of low boiling components.

In order to form the total curable epoxy formulation, a cure catalyst may be added to the final concentrated dispersion as an optional reagent. Cure catalysts accelerate curing of the total curable epoxy formulation. Typically, the catalyst is present in a range between about 10 parts per million (ppm) and about 10% by weight of the total curable epoxy formulation. Examples of alkyl onium cure catalysts include, but are not limited to bisaryliodonium salts (e.g. bis(dodecylphenyl)iodonium hexafluoroantimonate, (octyloxyphenyl, phenyl)iodonium hexafluoroantimonate, bisaryliodonium tetrakis(pentafluorophenyl)borate), triarylsulphonium hexafluoroantimonate, substituted aryl-dialkyl sulfonium hexafluoroantimonate, alkyl sulfonium hexafluoroantimonate (e.g. 3-methyl-2-butenyltetramethylene sulfonium hexafluoroantimonate), and combinations thereof. Preferably, the alkyl onium catalyst is bisaryliodonium hexafluoroantimonate. Additionally, an effective amount of a free-radical generating compound can be further added as an optional reagent such as aromatic pinacols, benzoinalkyl ethers, organic peroxides, and combinations thereof. The free radical generating compound facilitates decomposition of the alkyl onium salt at a lower temperature compared to analogous formulations where a free radical generating compound is not added.

Optionally, an epoxy hardener such as carboxylic acid-anhydride curing agents, phenolic resins, and amine epoxy hardeners may be present as optional reagents with the cure catalyst. The above formulation has acceptable stability at room temperature and can be cured by exposure to high temperature in range between about 100° C. and about 250° C. over a period in a range between about 5 minutes and about 3 hours to form high Tg material. The cure process can be accelerated by introduction of cure catalyst. In these cases, cure catalysts may be selected from typical epoxy curing catalysts that include but are not limited to amines, alkyl-substituted imidazole, imidazolium salts, phosphines, metal salts, salts of nitrogen-containing compounds with acidic compounds, and combinations thereof. The nitrogen-containing compounds include, for example, amine compounds, di-aza compounds, tri-aza compounds, polyamine compounds and combinations thereof. The acidic compounds include phenol, organo-substituted phenols, carboxylic acids, sulfonic acids and combinations thereof. A preferred catalyst is a salt of nitrogen-containing compound. Salts of nitrogen-containing compounds include, for example 1,8-diazabicyclo(5,4,0)-7-undecane. The salts of the nitrogen-containing compounds are available commercially, for example, as Polycat SA-1 and Polycat SA-102 available from Air Products.

Exemplary anhydride curing agents typically include methylhexahydrophthalic anhydride, 1,2-cyclohexanedicarboxylic anhydride, bicyclo[2.2.1]hept-5-ene-2,3-dicarboxylic anhydride, methylbicyclo[2.2.1]hept-5-ene-2,3-dicarboxylic anhydride, phthalic anhydride, pyromellitic dianhydride, hexahydrophthalic anhydride, dodecenylsuccinic anhydride, dichloromaleic anhydride, chlorendic anhydride, tetrachlorophthalic anhydride, and the like. Combinations comprising at least two anhydride curing agents may also be used. Illustrative examples are described in “Chemistry and Technology of the Epoxy Resins” B. Ellis (Ed.) Chapman Hall, New York, 1993 and in “Epoxy Resins Chemistry and Technology”, edited by C. A. May, Marcel Dekker, New York, 2nd edition, 1988.

Exemplary amine epoxy hardeners typically include aromatic amines, aliphatic amines, or combinations thereof. Aromatic amines include, for example, m-phenylene diamine, 4,4′-methylenedianiline, diaminodiphenylsulfone, diaminodiphenyl ether, toluene diamine, dianisidene, and blends of amines. Aliphatic amines include, for example, ethyleneamines, cyclohexyldiamines, alkyl substituted diamines, menthane diamine, isophorone diamine, and hydrogenated versions of the aromatic diamines. Combinations of amine epoxy hardeners may also be used. Illustrative examples of amine epoxy hardeners are also described in “Chemistry and Technology of the Epoxy Resins” B. Ellis (Ed.) Chapman Hall, New York, 1993.

Exemplary phenolic resins typically include phenol-formaldehyde condensation products, commonly named novolac or resole resins. These resins may be condensation products of different phenols with various molar ratios of formaldehyde. Illustrative examples of phenolic resin hardeners are also described in “Chemistry and Technology of the Epoxy Resins” B. Ellis (Ed.) Chapman Hall, New York, 1993. While these materials are representative of additives used to promote curing of the epoxy formulations, it will apparent to those skilled in the art that other materials such as but not limited to amino formaldehyde resins may be used as hardeners and thus fall within the scope of this invention.

Additionally, an organic compound containing hydroxyl moiety may be present with the carboxylic acid-anhydride curing agent. Examples of organic compounds containing hydroxyl moiety include alcohols, diols and bisphenols. The alcohol or diol may be straight chain, branched or cycloaliphatic and may contain from 2 to 12 carbon atoms. Examples of such diols include but are not limited to ethylene glycol; propylene glycol, i.e., 1,2- and 1,3-propylene glycol; 2,2-dimethyl-1,3-propane diol; 2-ethyl, 2-methyl, 1,3-propane diol; 1,3- and 1,5-pentane diol; dipropylene glycol; 2-methyl-1,5-pentane diol; 1,6-hexane diol; dimethanol decalin, dimethanol bicyclo octane; 1,4-cyclohexane dimethanol and particularly its cis- and trans-isomers; triethylene glycol; 1,10-decane diol; and combinations of any of the foregoing. Further examples of diols include bisphenols. Some illustrative, non-limiting examples of bisphenols include the dihydroxy-substituted aromatic hydrocarbons disclosed by genus or species in U.S. Pat. No. 4,217,438. Some preferred examples of dihydroxy-substituted aromatic compounds include 4,4′-(3,3,5-trimethylcyclohexylidene)-diphenol; 2,2-bis(4-hydroxyphenyl)propane (commonly known as bisphenol A); 2,2-bis(4-hydroxy-3,5-dimethylphenyl)propane; 2,4′-dihydroxydiphenylmethane; bis(2-hydroxyphenyl)methane; bis(4-hydroxyphenyl)methane; bis(4-hydroxy-5-nitrophenyl)methane; bis(4-hydroxy-2,6-dimethyl-3-methoxyphenyl)methane; 1,1-bis(4-hydroxyphenyl)ethane; 1,1-bis(4-hydroxy-2-chlorophenyl)ethane; 2,2-bis(3-phenyl-4-hydroxyphenyl)propane; bis(4-hydroxyphenyl)cyclohexylmethane; 2,2-bis(4-hydroxyphenyl)-1-phenylpropane; 2,2,2′,2′-tetrahydro-3,3,3′,3′-tetramethyl-1,1′-spirobi[1H-indene]-6,6′-diol (SBI); 2,2-bis(4-hydroxy-3-methylphenyl)propane (commonly known as DMBPC); resorcinol; and C₁₋₃ alkyl-substituted resorcinols.

Most typically, 2,2-bis(4-hydroxyphenyl)propane is the preferred bisphenol compound. Combinations of organic compounds containing hydroxyl moiety can also be used in the present invention.

A reactive organic diluent may also be added to the total curable epoxy formulation to decrease the viscosity of the composition. Examples of reactive diluents include, but are not limited to, 3-ethyl-3-hydroxymethyl-oxetane, dodecylglycidyl ether, 4-vinyl-1-cyclohexane diepoxide, di(Beta-(3,4-epoxycyclohexyl)ethyl)-tetramethyldisiloxane, and combinations thereof. An unreactive diluent may also be added to the composition to decrease the viscosity of the formulation. Examples of unreactive diluents include, but are not limited to toluene, ethylacetate, butyl acetate, 1-methoxy propyl acetate, ethylene glycol, dimethyl ether, and combinations thereof. The total curable epoxy formulation can be blended with a filler which can include, for example, fumed silica, fused silica such as spherical fused silica, alumina, carbon black, graphite, silver, gold, aluminum, mica, titania, diamond, silicone carbide, aluminum hydrates, boron nitride, and combinations thereof. When present, the filler is typically present in a range between about 10 weight % and about 95 weight %, based on the weight of the total epoxy curable formulation. More typically, the filler is present in a range between about 20 weight % and about 85 weight %, based on the weight of the total curable epoxy formulation.

Adhesion promoters can optionally be employed with the total curable epoxy formulation such as trialkoxyorganosilanes (e.g. γ-aminopropyltrimethoxysilane, 3-glycidoxypropyltrimethoxysilane, bis(trimethoxysilylpropyl)fumarate), aminoethylaminopropyltrimethoxysilane and combinations thereof used in an effective amount which is typically in a range between about 0.01% by weight and about 2% by weight of the total curable epoxy formulation.

Flame retardants may optionally be used in the total curable epoxy formulation of the present invention in a range between about 0.5 weight % and about 20 weight % relative to the amount of the total curable epoxy formulation. Examples of flame retardants in the present invention include phosphoramides, triphenyl phosphate (TPP), resorcinol diphosphate (RDP), bisphenol-a-disphosphate (BPA-DP), organic phosphine oxides, halogenated epoxy resin (tetrabromobisphenol A), metal oxide, metal hydroxides, salts of phosphorus compounds and combinations thereof.

The composition of the present invention may by hand mixed but also can be mixed by standard mixing equipment such as dough mixers, chain can mixers, planetary mixers, twin screw extruder, two or three roll mill and the like.

Formulations as described in the present invention are dispensable and have utility in devices in electronics such as computers, semiconductors, or any device where underfill, overmold, or combinations thereof is needed. Underfill encapsulant is used to reinforce physical, mechanical, and electrical properties of solder bumps that typically connect a chip and a substrate. Underfilling may be achieved by any method known in the art. The conventional method of underfilling includes dispensing the underfill material in a fillet or bead extending along two or more edges of the chip and allowing the underfill material to flow by capillary action under the chip to fill all the gaps between the chip and the substrate. Other exemplary methods include no-flow underfill, transfer molded underfill, wafer level underfill, and the like. The process of no-flow underfilling includes first dispensing the underfill encapsulant material on the substrate or semiconductor device, followed by placement of the chip on the substrate and third performing the solder bump reflowing and underfill encapsulant curing simultaneously. The process of transfer molded underfilling includes placing a chip and substrate within a mold cavity and pressing the underfill material into the mold cavity. Pressing the underfill material fills the air spaces between the chip and substrate with the underfill material. The wafer level underfilling process includes dispensing underfill materials onto the wafer before dicing into individual chips that are subsequently mounted in the final structure via flip-chip type operations. The material has the ability to fill gaps in a range between about 30 microns and about 500 microns.

Curing typically occurs at a temperature in a range between about 50° C. and about 250° C., more typically in a range between about 120° C. and about 225° C., at a pressure in a range between about 1 atmosphere (atm) and about 5 tons pressure per square inch, more typically in a range between about 1 atmosphere and about 1000 pounds per square inch (psi). In addition, curing may typically occur over a period in a range between about 30 seconds and about 5 hours, and more typically in a range between about 90 seconds and about 30 minutes. Optionally, the cured encapsulants can be post-cured at a temperature in a range between about 130° C. and about 250° C., more typically in range between about 150° C. and about 170° C. over a period in a range between about 1 hour and about 4 hours.

In order that those skilled in the art will be better able to practice the present invention, the following examples are given by way of illustration and not by way of limitation.

### EXAMPLES

The following section provides experimental details on the preparation of the functionalized colloidal silica samples as well as properties of epoxy formulations that incorporate these materials. The addition of filler to a polymer system typically gives an increase in modulus without a change in glass transition temperature, resulting in a heat distortion temperature that is unchanged. However, the data in the following tables substantiate the assertion that an unexpected increase in glass transition temperature can be obtained with the use of the appropriate sized functionalized colloidal silica. Resins with appropriate functionalized colloidal silica also permit formulation of molding compounds with acceptable spiral flow and low CTE.

### Example 1

### Preparation of Functionalized 5 nm Colloidal Silica Pre-Dispersion

The following general procedure was used to prepare functionalized 5 nm colloidal silica pre-dispersions. A mixture of aqueous colloidal silica (60 grams (g); 15% silica, Nalco 2326), isopropanol (92.5 g), 1-methoxy-2-propanol (154.3 g) and phenyltrimethoxysilane (1.8 g, Aldrich) was heated and stirred at 60-70° C. for 3 hours to give a clear suspension. The resulting mixture was stored at room temperature.

### Example 2

### Preparation of Functionalized Colloidal Silica Dispersions

The pre-dispersion (Example 1) was blended with UVR6105 epoxy resin from Dow Chemical Company (Table 1). The mixture was vacuum stripped at 60° C. at 1 mmHg to the constant weight to yield a viscous (VS) or thixotropic (TF) fluid (Table 1).

TABLE 1

Run number

| | 1 | 2 | 3 |
|---|---|---|---|
| UVR6105/g | 26.8 | 20.5 | 16.8 |
| Properties | | | |
| Yield/g | 37.9 | 31.9 | 27.9 |
| % of Functional | 29.2 | 35.6 | 39.8 |
| CS | | | |
| Viscosity at 25° C. | TF | TF | VS |

### Example 3

### Functionalized Colloidal Silica Capping with Silylating Agent

Functionalized colloidal silica (FCS) dispersions could be capped with hexamethyldisilazane (HMDZ). The solution from Example 1 was partially concentrated to remove 154 g (amount equal to the methoxypropanol) at 60° C. at 60 Torr. HMDZ (17.1 g, Aldrich) was added and the solution was heated to reflux for an hour at 120° C. The mixture was cooled down to room temperature. The clear dispersion of functionalized colloidal silica was blended with 28.4 g of UVR6105 from Dow Chemical Company and vacuum stripped at 60° C. at 1 mmHg to the constant weight to yield a thixotropic fluid with 30.3% of FCS (Run number 4).

### Example 4

### Preparation of Total Curable Epoxy Formulation

A blend of functionalized colloidal silica epoxy resin was blended with methylhexahydrophthalic anhydride (2.19 g, MHHPA, Aldrich). Samples could be cured in the absence of any catalyst. However, catalyst such as dibutyltin dilaurate (14 mg, DBTDL, Aldrich), POLYCAT SA-1 (14 mg, Air Products and Chemicals), aluminum acetylacetonate (available from Aldrich) or triphenylphosphine (available from Aldrich) was added as optional reagent to change the curing chemistry as seen in Table 2. Samples were cured at 150° C. for 3 hours. Properties of the cured specimens are shown in Table 2.

Tg and CTE were measured using Perkin Elmer Thermo-mechanical Analyzer TMA7 in the temperature range from 25° C. to 290° C. at a heating rate of 10° C./min.

TABLE 2

| | | | | | CTE | |
|---|---|---|---|---|---|---|
| Run | Resin | MHHPA | | | below | |
| # | (g)* | (g) | Catalyst | Tg | Tg | Appearance |
| 5 | Run 1 | 2.19 | DBTDL | 237 | 52 | Transparent |
| | (3.56 g) | | | | | |
| 6 | Run 1 | 2.19 | POLYCAT | 215 | 53 | Transparent |
| | (3.56 g) | | SA-1 | | | |
| 7 | Run 1 | 2.19 | none | 235 | 53 | Transparent |
| | (3.56 g) | | | | | |
| 8 | Run 4 | 2.19 | DBTDL | 220 | 57 | Transparent |
| | (3.62 g) | | | | | |
| 9 | Run 4 | 2.19 | POLYCAT | 200 | 55 | Transparent |
| | (3.62 g) | | SA-1 | | | |
| 10 | Run 4 | 2.19 | none | 222 | 54 | Transparent |
| | (3.62 g) | | | | | |

*Amount of resin calculated to provide 2.52 g of UVR 6105.

Samples with DBTDL as the catalyst showed better fluxing behavior (compared to samples without any catalyst added). Samples with POLYCAT SA-1 as the catalyst showed better adhesion properties (compared to samples without any catalyst added). The curing kinetics also showed dependence on the amount of POLYCAT SA-1 used. Samples cured faster as the amount of POLYCAT SA-1 was increased.

### Example 5

### Effect of Colloidal Silica Particle Size on Tg

Functionalized 20 nm and 40-50 nm colloidal silica dispersions were prepared in a similar fashion as Examples 1-4 with DBTDL as the catalyst. The average Tg obtained (different wt % of functionalized colloidal silica for different particle size) are listed in Table 3 for comparison. The average Tg of the pure resin without any FCS was about 180° C.

TABLE 3

| Particle Size (nm) | Tg (° C.) |
|---|---|
| 5 | 235 |
| 20 | 185 |
| 40-50 | 160 |

As seen in Table 3, an unexpected increase in glass transition temperature can be obtained with the use of the appropriate sized functionalized colloidal silica. As the particle size of the functionalized colloidal silica decreased, the glass transition temperature of the formulation increased.

While embodiments have been shown and described, various modifications and substitutions may be made thereto without departing from the spirit and the scope of the invention. Accordingly, it is to be understood that the present invention has been described by way of illustration and not limitation. wherein the encapsulant comprises at least one epoxy monomer, phenyltrimethoxysilane functionalized colloidal silica having a particle size in a range between about 2 nanometers and about 10 nanometers, a cure catalyst comprising salt of nitrogen-containing compound, and an anhydride curing agent wherein the glass transition temperature of the epoxy formulation is greater than about 200° C.

1. A curable epoxy formulation comprising at least one epoxy monomer, at least one organofunctionalized colloidal silica having a particle size in a range between about 2 nanometers and about 20 nanometers, and optional reagents wherein the organofunctionalized colloidal silica substantially increases the glass transition temperature of the epoxy formulation.

2. The curable epoxy formulation in accordance with claim 1, wherein the organofunctionalized colloidal silica has a particle size in a range between about 2 nanometers and about 10 nanometers.

3. The curable epoxy formulation in accordance with claim 1 having a glass transition temperature greater than about 200° C.

4. The curable epoxy formulation in accordance with claim 3 having a glass transition temperature greater than about 220° C.

5. The curable epoxy formulation in accordance with claim 1, wherein the organofunctional colloidal silica comprises up to about 80 weight % of silicon dioxide, based on the total weight of the total curable epoxy formulation.

6. The curable epoxy formulation in accordance with claim 1, wherein the colloidal silica is functionalized with an organoalkoxysilane.

7. The curable epoxy formulation in accordance with claim 6, wherein the organoalkoxysilane comprises phenyltrimethoxysilane.

8. The curable epoxy formulation in accordance with claim 6, wherein the colloidal silica is further functionalized with a capping agent.

9. The curable epoxy formulation in accordance with claim 8, wherein the capping agent comprises a silylating agent

10. The curable epoxy formulation in accordance with claim 9, wherein the silylating agent comprises hexamethyldisilazane.

11. The curable epoxy formulation in accordance with claim 1, further comprising at least one organic diluent.

12. The curable epoxy formulation in accordance with claim 11, wherein the organic diluent comprises 3-ethyl-3-hydroxymethyl-oxetane.

13. The curable epoxy formulation in accordance with claim 1, wherein the epoxy monomer comprises a cycloaliphatic epoxy monomer, an aliphatic epoxy monomer, an aromatic epoxy monomer, a silicone epoxy monomer, or combinations thereof.

14. The curable epoxy formulation in accordance with claim 1, wherein the optional reagent comprises an alkyl onium cure catalyst.

15. The curable epoxy formulation in accordance with claim 14, wherein the alkyl onium catalyst comprises bisaryliodonium hexafluoroantimonate.

16. The curable epoxy formulation in accordance with claim 14, wherein the optional reagent further comprises an effective amount of a free-radical generating compound.

17. The curable epoxy formulation in accordance with claim 1, wherein the optional reagent comprises at least one epoxy hardener.

18. The curable epoxy formulation in accordance with claim 17, wherein the epoxy hardener comprises an anhydride curing agent, a phenolic resin, an amine epoxy hardener, or combinations thereof.

19. The curable epoxy formulation in accordance with claim 18, wherein the epoxy hardener comprises an anhydride curing agent.

20. The curable epoxy formulation in accordance with claim 19, wherein the anhydride curing agent comprises methylhexahydrophthalic anhydride.

21. The curable epoxy formulation in accordance with claim 17, wherein the optional reagent further comprises a cure catalyst comprising amines, phosphines, metal salts, salts of a nitrogen-containing compounds, or combinations thereof.

22. The curable epoxy formulation in accordance with claim 21, wherein the cure catalyst comprises salts of a nitrogen-containing compound.

23. The curable epoxy formulation in accordance with claim 1, wherein the cured formulation provides a coefficient of thermal expansion of below about 50 ppm/° C.

24. The curable epoxy formulation in accordance with claim 1, further comprising at least one filler, at least one adhesion promoter, at least one flame retardant, or combination thereof.

25. A curable epoxy formulation comprising at least one epoxy monomer, phenyltrimethoxysilane functionalized colloidal silica having a particle size in a range between about 2 nanometers and about 10 nanometers,
a cure catalyst comprising a salt of nitrogen-containing compound, and
an anhydride curing agent wherein the glass transition temperature of the epoxy formulation is greater than about 200° C.

26. A semiconductor package comprising at least one chip, at least one substrate, and an encapsulant,
wherein the encapsulant encapsulates at least a portion of the chip on the substrate and wherein the encapsulant comprises at least one epoxy monomer, at least one organofunctionalized colloidal silica having a particle size in a range between about 2 nanometers and about 20 nanometers, and optional reagents wherein the organofunctionalized colloidal silica substantially increases the glass transition temperature of the epoxy formulation.

27. The semiconductor package in accordance with claim 26, wherein the organofunctionalized colloidal silica has a particle size in a range between about 2 nanometers and about 10 nanometers.

28. The semiconductor package in accordance with claim 26, wherein the encapsulant has a glass transition temperature greater than about 200° C.

29. The semiconductor package in accordance with claim 28, wherein the encapsulant has a glass transition temperature greater than about 220° C.

30. The semiconductor package in accordance with claim 26, wherein the organofunctional colloidal silica comprises up to about 80 weight % of silicon dioxide, based on the total weight of the total curable epoxy formulation.

31. The semiconductor package in accordance with claim 26, wherein the colloidal silica is functionalized with an organoalkoxysilane.

32. The semiconductor package in accordance with claim 31, wherein the organoalkoxysilane comprises phenyltrimethoxysilane.

33. The semiconductor package in accordance with claim 31, wherein the colloidal silica is further functionalized with at least one capping agent.

34. The semiconductor package in accordance with claim 33, wherein the capping agent comprises a silylating agent.

35. The semiconductor package in accordance with claim 26, wherein the encapsulant further comprises at least one organic diluant.

36. The semiconductor package in accordance with claim 35, wherein the organic diluant comprises 3-ethyl-3-hydroxymethyl-oxetane.

37. The semiconductor package in accordance with claim 26, wherein the epoxy monomer comprises a cycloaliphatic epoxy monomer, an aliphatic epoxy monomer, an aromatic epoxy monomer, a silicone epoxy monomer, or combinations thereof.

38. The semiconductor package in accordance with claim 26, wherein the optional reagent comprises an alkyl onium cure catalyst.

39. The semiconductor package in accordance with claim 38, wherein the cure catalyst comprises bisaryliodonium hexafluoroantimonate.

40. The semiconductor package in accordance with claim 38, wherein the optional reagent further comprises an effective amount of a free radical generating compound.

41. The semiconductor package in accordance with claim 26, wherein the optional reagent comprises at least one epoxy hardener.

42. The semiconductor package in accordance with claim 41, wherein the epoxy hardener comprises an anhydride curing agent, a phenolic resin, an amine epoxy hardener, or combinations thereof.

43. The semiconductor package in accordance with claim 42, wherein the epoxy hardener comprises an anhydride curing agent.

44. The semiconductor package in accordance with claim 43, wherein the anhydride curing agent comprises methylhexahydrophthalic anhydride.

45. The semiconductor package in accordance with claim 41, wherein the optional reagent further comprises a cure catalyst comprising amines, phosphines, metal salts, salts of a nitrogen-containing compound, or combinations thereof.

46. The semiconductor package in accordance with claim 45, wherein the cure catalyst comprises salts of a nitrogen-containing compound.

47. The semiconductor package in accordance with claim 26, wherein the cured encapsulant provides a coefficient of thermal expansion of below about 50 ppm/° C.

48. The semiconductor package in accordance with claim 26, wherein the encapsulant further comprises at least one filler, at least one adhesion promoter, at least one flame retardant, or combination thereof.

49. The semiconductor package in accordance with claim 26, wherein the encapsulant is dispensed via an underfill method.

50. The semiconductor package in accordance with claim 49, wherein the underfill method comprises no-flow underfill, transfer molded underfill, or wafer level underfill.

51. A semiconductor package comprising a chip, a substrate, and an encapsulant, wherein the encapsulant encapsulates at least a portion of a chip on a substrate and wherein the encapsulant comprise at least one epoxy monomer, phenyltrimethoxysilane functionalized colloidal silica having a particle size in a range between about 2 nanometers and about 10 nanometers, a cure catalyst comprising salt of nitrogen-containing compound, and anhydride curing agent wherein the glass transition temperature of the epoxy formulation is greater than about 200°C.
